(19) United States
(12) Patent Application Publication
(10) Pub. No.: US 2025/0359312 A1
(43) Pub. Date: Nov. 20, 2025

(54) SEMICONDUCTOR DEVICE MANUFACTURING ON ASSEMBLED WAFER

(71) Applicant: Taiwan Semiconductor Manufacturing Company, Ltd., Hsinchu (TW)

(72) Inventors: Han-De Chen, Hsinchu City (TW); Chen-Fong Tsai, Hsinchu City (TW); Kuan-Kan Hu, Hsinchu (TW); Ku-Feng Yang, Hsinchu County (TW); Chi On Chui, Hsinchu City (TW)

(21) Appl. No.: 19/283,551

(22) Filed: Jul. 29, 2025

Related U.S. Application Data
(63) Continuation of application No. 18/360,038, filed on Jul. 27, 2023.
(60) Provisional application No. 63/491,778, filed on Mar. 23, 2023.

(51) Int. Cl. H10D 84/85; H10D 30/43; H10D 30/67; H10D 62/10; H10D 64/23; H10D 84/01; H10D 84/03

(52) U.S. Cl. CPC H10D 84/85; H10D 30/43; H10D 30/6735; H10D 62/121; H10D 64/258; H10D 84/0167; H10D 84/038

(57) ABSTRACT

Semiconductor structures and processes of forming the same are provided. A semiconductor structure according to the present disclosure includes a first bottom source/drain feature and a second bottom source/drain feature disposed over a substrate, a plurality of bottom channel members extending between and in contact with the first bottom source/drain feature and the second bottom source/drain feature, a first bonding layer over the plurality of bottom channel members, a second bonding layer disposed directly on the first bonding layer, a first top source/drain feature disposed directly over the first bottom source/drain feature, a second top source/drain feature disposed directly over the second bottom source/drain feature, and a plurality of top channel members disposed over the second bonding layer and extending between and in contact with the first top source/drain feature and the second top source/drain feature.

### PRIORITY DATA

This application is a continuation application of U.S. patent application Ser. No. 18/360,038, filed Jul. 27, 2023, which claims priority to U.S. Provisional Patent Application No. 63/491,778, filed on Mar. 23, 2023, which is hereby incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The channel region of an MBC transistor may be formed from nanowires, nanosheets, other nanostructures, and/or other suitable structures. The shapes of the channel region have also given an MBC transistor alternative names such as a nanosheet transistor or a nanowire transistor.

As the semiconductor industry further progresses into advanced technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. Formation of a local interconnect feature in such a C-FET may involve forming an opening through an epitaxial source/drain feature or certain dielectric isolation features adjacent the epitaxial source/drain feature.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor device having a vertical C-FET structure, according to one or more aspects of the present disclosure.

FIGS. 2-17 illustrate fragmentary cross-sectional views of a workpiece undergoing various fabrication processes in the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A stacked multi-gate device refers to a semiconductor device that includes a bottom multi-gate device and a top multi-gate device stacked over the bottom multi-gate device. When the bottom multi-gate device and the top multi-gate device are of different conductivity types, the stacked multi-gate device may be a complementary field effect transistor (C-FET). The multi-gate devices in a C-FET may be FinFETs or MBC transistors. There may be multiple ways to form a C-FET when the multi-gate devices therein are MBC transistors. For example, when active regions of the bottom multi-gate device and the top multi-gate device are patterned simultaneously, an alternating stack of two types of semiconductor layers may be epitaxially deposited over a substrate. In order to form a dielectric layer to insulate the active region of the of the bottom multi-gate device from the active region of the top multi-gate, the alternating stack may include a middle layer that has different germanium content. The different germanium content may create additional lattice mismatch that may result in undesirable defects. Additionally, formation of the later forming semiconductor layers in an alternating stack may create high thermal budget for prior forming semiconductor layers, especially when the alternating stack includes a number of layers to form both a bottom MBC transistor and a top MBC transistor.

The present disclosure provides methods to form C-FET structure from a composite stack that includes two half stacks bonded together. In an example process, a first stack of a first plurality of channel layers interleaved by a first plurality of sacrificial layer is formed on a first substrate. A second stack of a second plurality of channel layers interleaved by a second plurality of sacrificial layer is formed on a second substrate. After formation of a first bonding layer on the first stack and a second bonding layer on the second stack, the second stack is flipped upside down to bond to the first stack. The second substrate is then removed to form a composite stack on the first substrate. The present disclosure further provides processes to form a C-FET structure on the composite stack. Because the first stack and the second stack are epitaxially grown separately, the first stack is less likely to be affected by the thermal energy used in the formation of the second stack. Additionally, direct bonding of the first bonding layer and the second bonding layer eliminates the need to form a middle semiconductor layer that has different composition. Because the different composition of the middle semiconductor layer tends to result in lattice mismatch, methods of the present disclosure help reduce lattice mismatch and improve quality of the second stack.

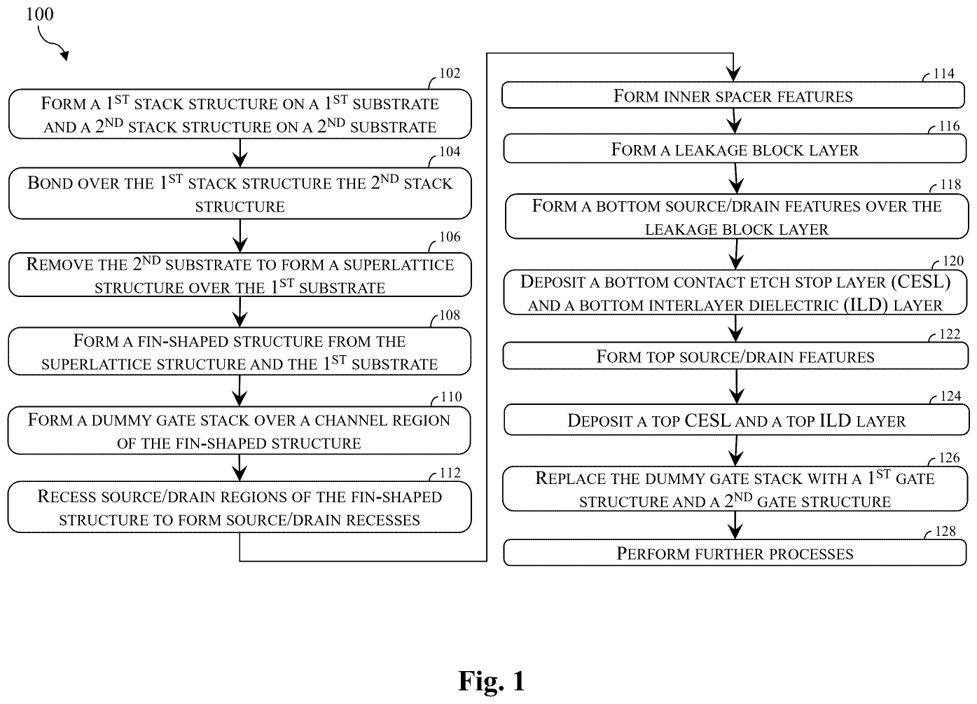

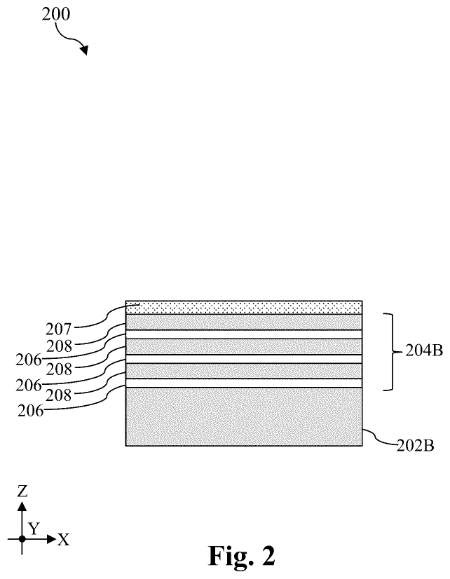

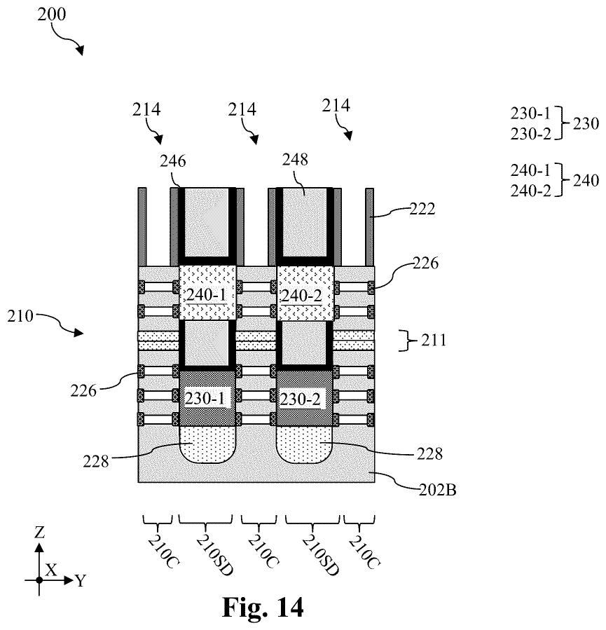

The various aspects of the present disclosure will now be described in more detail with reference to the figures. In that regard, FIG. 1 is a flowchart illustrating method 100 for forming a semiconductor device according to various aspects of the present disclosure. Method 100 is merely an example and is not intended to limit the present disclosure to what is explicitly illustrated in method 100. Additional steps may be provided before, during and after method 100, and some steps described can be replaced, eliminated, or moved around for additional embodiments of the method. Not all steps are described herein in detail for reasons of simplicity. Method 100 is described below in conjunction with FIGS. 2-17, which are fragmentary cross-sectional views of a workpiece 200 at different stages of fabrication according to embodiments of method 100. Because the workpiece 200 will be fabricated into a semiconductor device 200 upon conclusion of the fabrication processes, the workpiece 200 may be referred to as a semiconductor device 200 as the context requires. Additionally, throughout the present application and across different embodiments, like reference numerals denote like features with similar structures and compositions, unless otherwise excepted. Source/drain region(s) may refer to a source or a drain, individually or collectively, dependent upon the context.

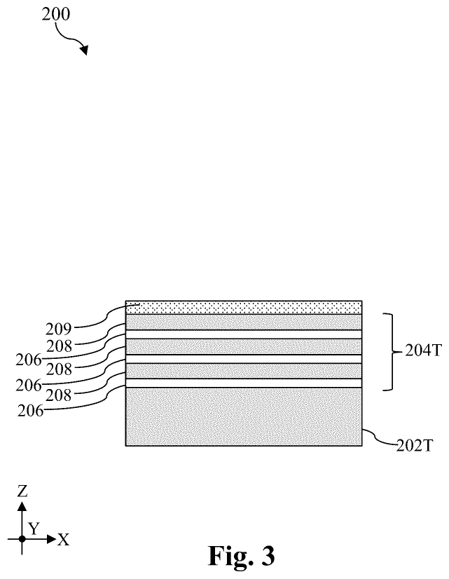

Referring to FIGS. 1, 2 and 3, method 100 includes a block 102 where a first stack structure 204B is formed on a first substrate 202B and a second stack structure 204T is formed a second substrate 202T. Each of the first substrate 202B in FIG. 2 and the second substrate 202T in FIG. 3 may be a silicon (Si) substrate. In some other embodiments, each of the first substrate 202B and the second substrate 202T may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). Each of the first substrate 202B and the second substrate 202T may also include an insulating layer, such as a silicon oxide layer, to have a silicon-on-insulator (SOI) structure. Although not explicitly shown in the figures, the first substrate 202B may include an n-type well region and a p-type well region for fabrication of transistors of different conductivity types. When present, each of the n-type well and the p-type well is formed in the first substrate 202B and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the first substrate 202B. In one embodiment, the first substrate 202B and the second substrate 202T shares the same composition.

Each of the first stack structure 204B and the second stack structure 204T includes a plurality of channel layers 208 interleaved by a plurality of sacrificial layers 206. The channel layers 208 and the sacrificial layers 206 may have different semiconductor compositions. In some implementations, the channel layers 208 are formed of silicon (Si) and sacrificial layers 206 are formed of silicon germanium (SiGe). In these implementations, the additional germanium content in the sacrificial layers 206 allow selective removal or recess of the sacrificial layers 206 without substantial damages to the channel layers 208. The sacrificial layers 206 and the channel layers 208 are deposited alternatingly, one-after-another, to form the first stack structure 204B or the second stack structure 204T. It is noted that each of the first stack 204B in FIG. 2 and the second stack structure 204T in FIG. 3 includes two (2) layers of the channel layers 208 interleaved by three (3) layers of sacrificial layers 206, which is for illustrative purposes only and not intended to be limiting beyond what is specifically recited in the claims. It can be appreciated that any number of the channel layers 208 can be included in each of the first stack 204B and the second stack structure 204T. The number of layers depends on the desired number of channels members for the top MBC transistor and the bottom MBC transistor. In some embodiments, the number of the channel layers 208 in each of the first stack 204B and the second stack structure 204T may be between 2 and 5.

The channel layers 208 in the first stack structure 204B will provide channel members of a bottom MBC transistor, and the channel layers 208 in the second stack structure 204T will provide channel members of a top MBC transistor. The term “channel member(s)” is used herein to designate any material portion for channel(s) in a transistor with nanoscale dimensions, and having an elongate shape, regardless of the cross-sectional shape of this portion. Channel members may come in forms of nanowires, nanosheet, or other nanostructures and may have cross-sections that are circular, oval, race-track shaped, rectangular, or square.

Each of the channel layers 208 and the sacrificial layers 206 in the first stack structure 204B and the second stack 204T are deposited one over another using vapor-phase epitaxy (VPE), ultra-high vacuum chemical vapor deposition (UHV-CVD), molecular beam epitaxy (MBE), and/or other suitable epitaxy deposition processes. Notably, the process temperature required to deposit a channel layer 208 is higher than that required to deposit a sacrificial layer 206. In some instances, the deposition temperature of a silicon channel layer 208 may be between about 500° C. and about 600° C. while the deposition temperature a silicon germanium sacrificial layer 206 may be between about 400° C. and about 500° C. When the process temperature is greater than about 600° C., risks are that germanium in the deposited silicon germanium sacrificial layers 206 may start diffusing to adjacent channel layers 208. By forming the first stack structure 204B and the second stack structure 204T separating, sacrificial layers 206 that are formed earlier may experience less undesirable heat cycles, thereby reducing undesirable germanium diffusion.

After formation of the first stack structure 204B, a first bonding layer 207 is deposited over the first stack structure 204B. In order to function properly during the subsequent bonding step, it is desirable that the first bonding layer 207 is dense. In some embodiments, the first bonding layer 207 and the second bonding layer 209 may include silicon oxide, silicon carbonitride, silicon nitride, silicon oxynitride, or silicon oxycarbonitride. In one embodiment, the first bonding layer 207 is deposited over the first stack structure 204B using atomic layer deposition (ALD), plasma enhanced chemical vapor deposition (PECVD), or CVD to ensure that the first bonding layer 207 possess the necessary density. In another embodiment, the first bonding layer 207 may be deposited using physical vapor deposition (e.g., sputtering) and then the deposited first bonding layer 207 may undergo an anneal to densify the first bonding layer 207. The densification anneal may include an anneal temperature between about 500° C. and about 600° C. While a higher anneal temperature may be desirable in terms of effect of densification, annealing at a temperature greater than 600° C. may cause interdiffusion of germanium atoms in the sacrificial layers 206. Similarly, a second bonding layer 209 is deposited over the second stack structure 204T. To prevent wafer warpage, a composition and formation process of the second bonding layer 209 may be substantially the same as those of the first bonding layer 207. This ensures that both the first bonding layer 207 and the second bonding layer 209 have the same coefficient of thermal expansion (CTE). Each of the first bonding layer 207 and the second bonding layer 209 may have a thickness between about 1 nm and about 100 nm. In some embodiments, the first bonding layer 207 and the second bonding layer 209 share the same thickness. In some other embodiments, the first bonding layer 207 and the second bonding layer 209 may have different thicknesses.

In some embodiments represented in FIGS. 2 and 3, the first bonding layer 207 is deposited on a topmost channel layer 208 of the first stack structure 204B and the second bonding layer 209 is directly deposited on a topmost channel layer 208 of the second stack structure 204T. The present disclosure is not so limited. Depending of the design, the first bonding layer 207 or the second bonding layer 209 may also be deposited directly on a topmost sacrificial layer 206. It is also possible that the first stack structure 204B and the second stack structure 204T have different numbers of channel layers 208 or sacrificial layers 206 such that one of the first bonding layer 207 is deposited on a channel layer 208 while the second bonding layer 209 is deposited on a sacrificial layer 206, or vice versa. In some embodiments, in the interest of efficient modulization, the first stack structure 204B and the first bonding layer 207 are identical to the second stack structure 204T and the second bonding layer 209. That way, manufacturers do not need to fabricate two different kinds of stack structures.

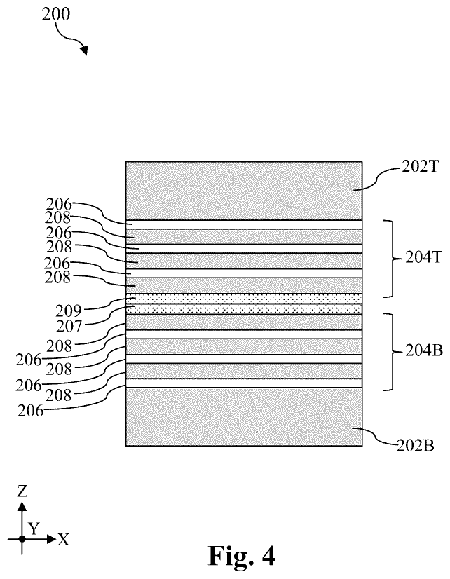

Referring to FIGS. 1 and 4, method 100 includes a block 104 where the second stack structure 204T is bonded over the first stack structure 204B. As shown in FIG. 4, the second stack structure 204T is bonded to the first stack structure 204B by directly bonding the second bonding layer 209 to the first bonding layer 207. That is, the second stack structure 204T and the second bonding layer 209, as a whole, are turned upside down for the bonding at block 104. To bond the first bonding layer 207 and the second bonding layer 209, their exposed surfaces are first treated with a nitrogen (N₂) plasma, an oxygen (O₂) plasma, or an argon (Ar) plasma to introduce surface dangling bonds (e.g., hydroxyl bond). After the treatment, surfaces of the first bonding layer 207 and the second bonding layer 209 are cleaned with deionized (DI) water. In some alternative embodiments, before the plasma treatment, the first bonding layer 207 and the second bonding layer 209 may be optionally cleaned to remove organic and metallic contaminants. In an example process, a mixture of ammonium hydroxide and hydrogen peroxide (SC1) and/or a mixture of hydrochloric acid and hydrogen peroxide (SC2) may be used to clean surfaces of the first bonding layer 207 and the second bonding layer 209. The mixture of ammonium hydroxide and hydrogen peroxide (SC1) may remove organic contaminants. The mixture of hydrochloric acid and hydrogen peroxide (SC2) may remove metallic contaminants. After the plasma treatment, the second bonding layer 209 is brought to direct contact with the first bonding layer 207. An anneal is performed to promote the van der Waals force bonding of the second bonding layer 209 to the first bonding layer 207. Because no active regions or gate structures have been formed on the first substrate 202B and the second substrate 202T, the bonding at block 104 only requires aligning the first substrate 202B and the second substrate 202T. For example, when both the first substrate 202B and the second substrate 202T are wafers with notches to indicate crystalline orientation, bonding at block 104 only requires aligning the two wafers as long as their notches. While the first bonding layer 207 and the second bonding layer 209 are bonded together at block 104, an observable interface may exist at an interface between them, indicating that they are once two separate layers.

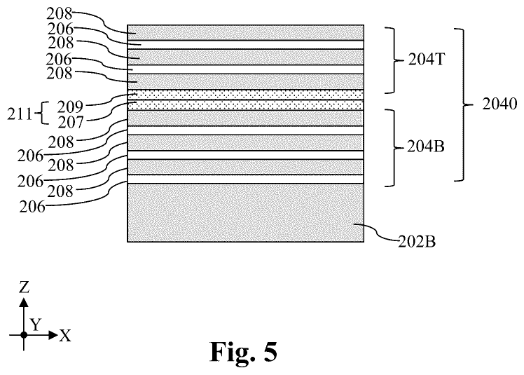

Referring to FIGS. 1 and 5, method 100 includes a block 106 where the second substrate 202T is removed to form a superlattice structure 2040. After the second stack structure 204T is bonded to the first stack structure 204B by way of the first bonding layer 207 and the second bonding layer 209, the second substrate 202T (shown in FIG. 4) is removed by a combination of mechanical grinding and chemical mechanical polishing (CMP). In one embodiment, the second substrate 202T is first mechanically ground to a suitable thickness and then the thinned second substrate 202T is removed by a CMP process. After the removal of the second substrate 202T, a superlattice 2040 is formed on the first substrate 202B. As shown in FIG. 5, the superlattice 2040 includes the first stack structure 204B, the first bonding layer 207, the second bonding layer 209, and the second stack structure 204T. For case of references, the first bonding layer 207 and the second bonding layer 209 may be referred to as bonding layers 211. Because the superlattice structure 2040 includes two stack structures bonded together by the bonding layers 211, it may also be referred to as a composite stack 2040 or an assembled stack 2040.

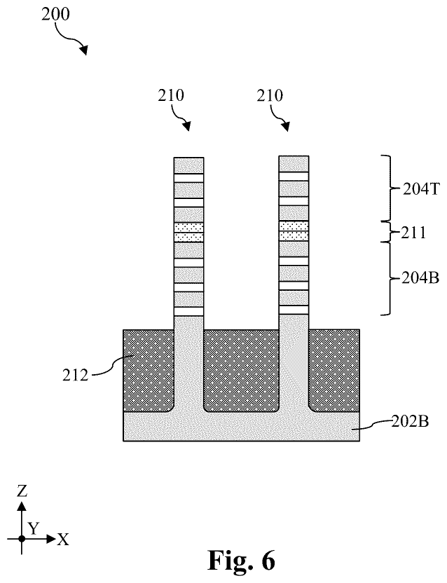

Referring to FIGS. 1 and 6, method 100 includes a block 108 where a fin-shaped structure 210 is formed from the superlattice structure 2040 and a portion of the first substrate 202B. For patterning purposes, a hard mask layer may be deposited over the superlattice structure 2040. The hard mask layer may be a single layer or a multilayer. In one example, the hard mask layer includes a silicon oxide layer and a silicon nitride layer over the silicon oxide layer. As shown in FIG. 6, the fin-shaped structure 210 extends vertically along the Z direction from the first substrate 202B and extends lengthwise along the Y direction. The fin-shaped structure 210 may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the superlattice structure 2040 and the first substrate 202B to form the fin-shaped structure 210. The etching process may include dry etching, wet etching, reactive ion etching (RIE), and/or other suitable processes.

After the fin-shaped structure 210 is formed, an isolation feature 212 is formed around the fin-shaped structure 210 to separate the fin-shaped structure 210 from an adjacent fin-shaped structure 210. The isolation feature 212 may also be referred to as a shallow trench isolation (STI) feature 212. In an example process, a dielectric material for the isolation feature is deposited over the workpiece 200, including the fin-shaped structure 210, using CVD, subatmospheric CVD (SACVD), flowable CVD, spin-on coating, and/or other suitable process. Then the deposited dielectric material is planarized and recessed to form the isolation feature 212. As shown in FIG. 6, the fin-shaped structure 210 rises above the isolation feature 212. The dielectric material for the isolation feature 212 may include silicon oxide, silicon oxynitride, fluorine-doped silicate glass (FSG), a low-k dielectric, combinations thereof, and/or other suitable materials. In the embodiments represented in FIG. 6, a base portion of the fin-shaped structure 210 that is formed from the first substrate 202B is buried in the isolation feature 212. This base portion may also be referred to as a base fin. In some embodiments represented in FIG. 6, the portion of the fin-shaped structure 210 that is formed from the superlattice structure 2040 rises above a top surface of the isolation feature 212.

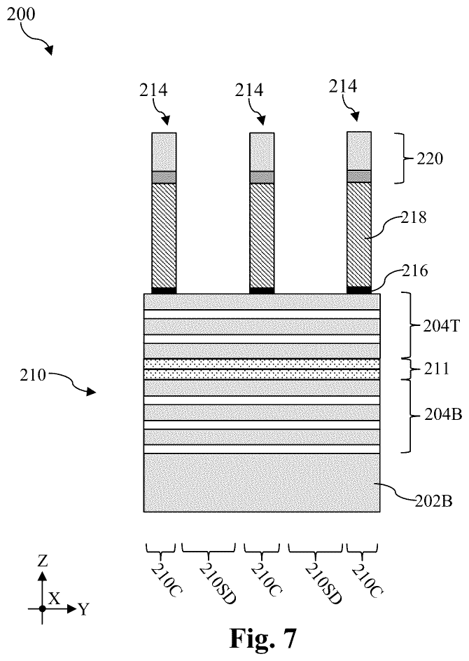

Referring to FIGS. 1 and 7, method 100 includes a block 110 where a dummy gate stack 214 is formed over a channel region 210C of the fin-shaped structure 210. In some embodiments, a gate replacement process (or gate-last process) is adopted where the dummy gate stack 214 serves as a placeholder for a functional gate structure. Other processes and configuration are possible. To form the dummy gate stack 214, a dummy dielectric layer 216, a dummy gate electrode layer 218, and a gate-top hard mask layer 220 are deposited over the workpiece 200. The deposition of these layers may include use of low-pressure CVD (LPCVD), CVD, plasma-enhanced CVD (PECVD), PVD, ALD, thermal oxidation, e-beam evaporation, or other suitable deposition techniques, or combinations thereof. The dummy dielectric layer 216 may include silicon oxide, the dummy gate electrode layer 218 may include polysilicon, and the gate-top hard mask layer 220 may be a multi-layer that includes silicon oxide and silicon nitride. Using photolithography and etching processes, the gate-top hard mask layer 220 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching (e.g., RIE etching), wet etching, and/or other etching methods. Like the fin-shaped structures 210, the dummy gate stack 214 may also be patterned using double-patterning or multiple-patterning techniques. Thereafter, using the patterned gate-top hard mask 220 as the etch mask, the dummy dielectric layer 216 and the dummy gate electrode layer 218 are then etched to form the dummy gate stack 214. The dummy gate stack 214 extends lengthwise along the X direction to wrap over the fin-shaped structure 210 and lands on the isolation feature 212. The portion of the fin-shaped structure 210 underlying the dummy gate stack 214 defines a channel region 210C. The channel region 210C and the dummy gate stack 214 also define source/drain regions 210SD that are not vertically overlapped by the dummy gate stack 214. The channel region 210C is disposed between two source/drain regions 210SD along the Y direction.

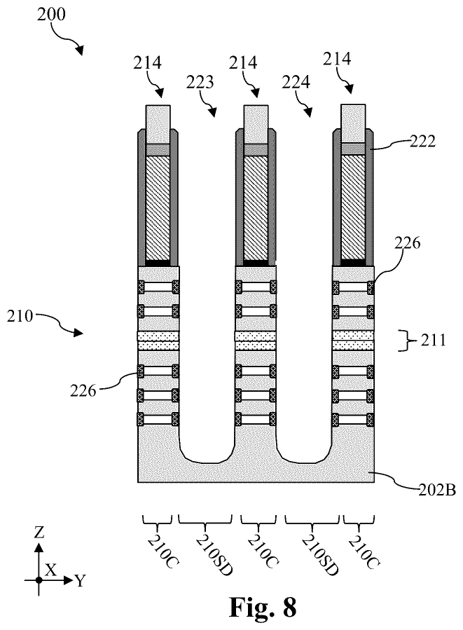

Referring to FIGS. 1 and 8, method 100 includes a block 112 where source/drain regions 210SD of the fin-shaped structure 210 are recessed to form a first source/drain recess 223 and a second source/drain recess 224. Operations at block 112 may include formation of at least one gate spacer layer 222 over the sidewalls of the dummy gate stack 214 before the source/drain regions 210SD are recessed. In some embodiments, the formation of the at least one gate spacer layer 222 includes deposition of one or more dielectric layers over the workpiece 200. In an example process, the one or more dielectric layers are conformally deposited using CVD, SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. After the deposition of the at least one gate spacer layer 222, the workpiece 200 is etched in an anisotropic etch process to form the first source/drain recess 223 and the second source/drain recess 224. The etch process at block 108 may be a dry etch process or a suitable etch process. An example dry etch process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. After operations at block 112, sidewalls of the sacrificial layers 206 and the channel layers 208 in the channel regions 210C are exposed in the first source/drain recess 223 and the second source/drain recess 224. Due to their elongated shapes, the first source/drain recess 223 may also be referred to as the first source/drain trench 223 and the second source/drain recess 224 may also be referred to as the second source/drain trench 224.

Referring to FIGS. 1 and 8, method 100 includes a block 114 where inner spacer features 226 are formed. At block 114, the sacrificial layers 206 exposed in the first source/drain recess 223 and the second source/drain recess 224 are selectively and partially recessed to form inner spacer recesses, while the exposed channel layers 208, the exposed first bonding layer 207 and the exposed second bonding layer 209 are substantially unetched. In an embodiment where the channel layers 208 consist essentially of silicon (Si) and sacrificial layers 206 consist essentially of silicon germanium (SiGe), the selective and partial recess of the sacrificial layers 206 may include a SiGe oxidation process followed by a SiGe oxide removal. In that embodiments, the SiGe oxidation process may include use of ozone (03). In some other embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include use of hydrogen fluoride (HF) or ammonium hydroxide (NH₄OH). After the formation of the inner spacer recesses, an inner spacer material layer is deposited over the workpiece 200, including in the inner spacer recesses. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess inner spacer material layer over the gate spacer layer and sidewalls of the channel layers 208, thereby forming the inner spacer features 226 as shown in FIG. 8. In some embodiments, the etch back process at block 110 may be a dry etch process that includes use of an oxygen-containing gas, hydrogen, nitrogen, a fluorine-containing gas (e.g., NF₃, CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof. It is noted that at block 114, the first bonding layer 207 and the second bonding layer 209, though exposed in the first source/drain recess 223 and the second source/drain recess 224, are substantially unetched and are not replaced with the inner spacer material. Additionally, a composition of the first bonding layer 207 and the second bonding layer 209 may be different from inner spacer material. For example, the first bonding layer 207 and the second bonding layer 209 may be more etch resistant than the inner spacer features 226 by having a greater carbon content, a greater nitrogen content, or both.

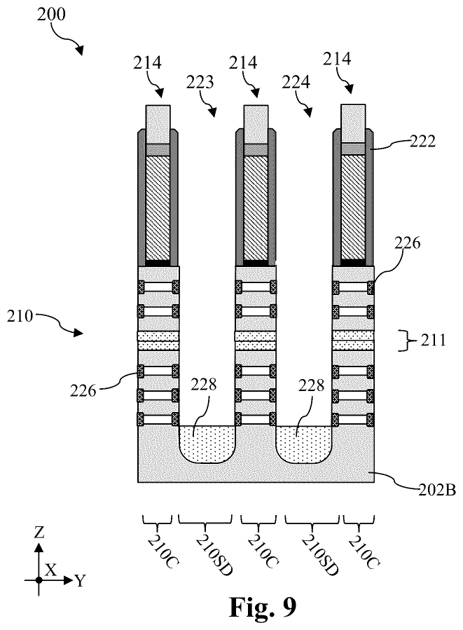

Referring to FIGS. 1 and 9, method 100 includes a block 116 where a leakage block layer 228 are formed in the first source/drain recess 223 and the second source/drain recess 224. The leakage block layer 228 functions to reduce leakage into the first substrate 202B. The leakage block layer 228 may include undoped semiconductor material or a dielectric material. In the depicted embodiments, the leakage block layer 228 includes an undoped semiconductor material, such as undoped silicon (Si), undoped silicon germanium (SiGe), or undoped germanium (Ge). In these embodiments, the leakage block layer 228 may be deposited using vapor-phase epitaxy (VPE), ultra-high vacuum chemical vapor deposition (UHV-CVD), molecular beam epitaxy (MBE), and/or other suitable epitaxy deposition processes.

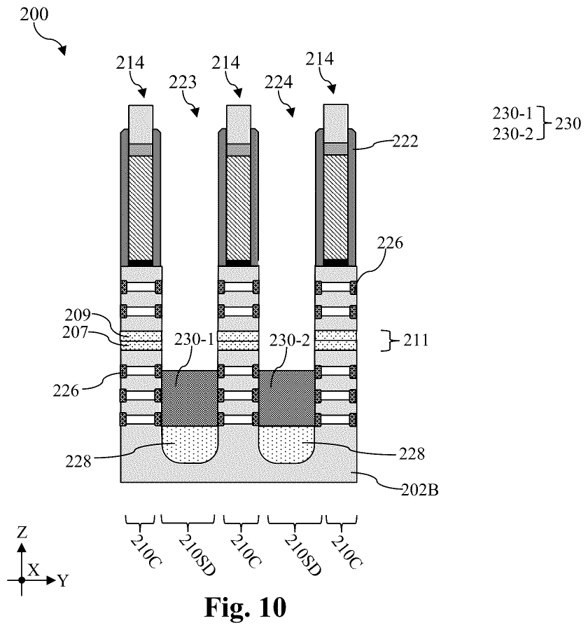

Referring to FIGS. 1 and 10, method 100 includes a block 118 where a first bottom source/drain feature 230-1 and a second bottom source/drain features 230-2 are formed over the leakage block layer 228. For case of reference, the first bottom source/drain feature 230-1 and the second bottom source/drain feature 230-2 may be collectively referred to as bottom source/drain features 230. Referring to FIG. 10, the bottom source/drain features 230 may be formed using an epitaxial process, such as VPE, UHV-CVD, MBE, and/or other suitable processes. The epitaxial growth process may use gaseous and/or liquid precursors, which interact with semiconductor surfaces. The epitaxial growth of bottom source/drain features 230 may take place from both the top surface of the leakage block layer 228 and the exposed sidewalls of the bottom channel layers 208. As illustrated in FIG. 10, the deposited bottom source/drain features 230 are in physical contact with (or adjoining) the channel layers 208 formed from the first stack structure 204B. Although the epitaxial growth of bottom source/drain features 230 is less likely to take place on surfaces of the inner spacer features 226, overgrowth of the bottom source/drain features 230 allow the bottom source/drain features 230 to merge over the inner spacer features 226. Depending on the design, the bottom source/drain features 230 may be n-type or p-type. In the depicted embodiments, the bottom source/drain features 230 are p-type source/drain features and may include silicon germanium (SiGe) doped with a p-type dopant, such as boron (B). In some alternative embodiments, the bottom source/drain features 230 may be n-type source/drain features and may include silicon (Si) doped with phosphorus (P). In these depicted embodiments, the bottom source/drain features 230 include boron doped silicon germanium (SiGe: B).

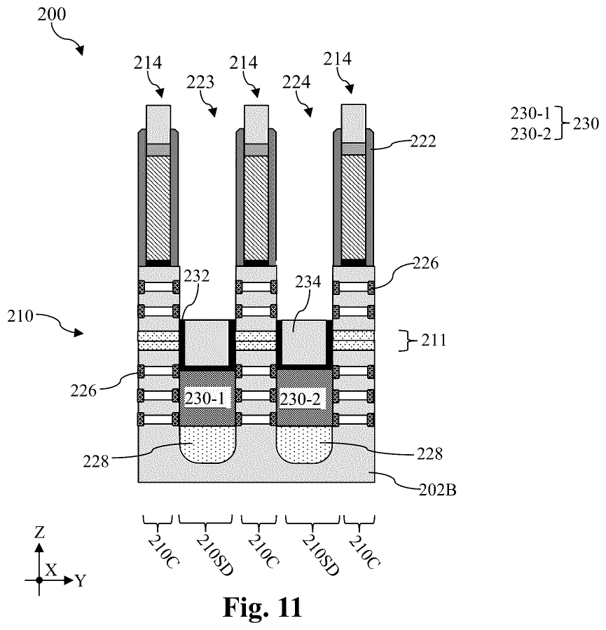

Referring to FIGS. 1 and 11, method 100 includes a block 120 where a bottom contact etch stop layer (CESL) 232 and a bottom interlayer dielectric (ILD) layer 234 are deposited. The bottom CESL 232 may include silicon nitride, silicon oxynitride, and/or other materials known in the art. The bottom ILD layer 234 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the bottom CESL 232 is first conformally deposited on the workpiece 200 by CVD, ALD, plasma-enhanced chemical vapor deposition (PECVD) process and/or other suitable deposition or oxidation processes and the bottom ILD layer 234 is deposited over the bottom CESL 232 by spin-on coating, FCVD, CVD, or other suitable deposition technique. In some embodiments, after formation of the bottom ILD layer 234, the workpiece 200 may be annealed to improve integrity of the bottom ILD layer 234. As shown in FIG. 11, the bottom CESL 232 and the bottom ILD layer 234 are etched back to exposed sidewalls of the channel layers 208 formed from the second stack structure 204T. The bottom CESL 232 is in direct contact with top surfaces of the bottom source/drain features 230 and sidewalls of the first bonding layer 207 and the second bonding layer 209. Additionally, the bottom CESL 232 is in direct contact with sidewalls of a channel layer 208 formed from the first stack structure 204B and a channel layer 208 formed from the second stack structure 204T. The bottom ILD layer 234 is spaced apart from top the surfaces of the bottom source/drain features 230 and sidewalls of the first bonding layer 207 and the second bonding layer 209 by the bottom CESL 232.

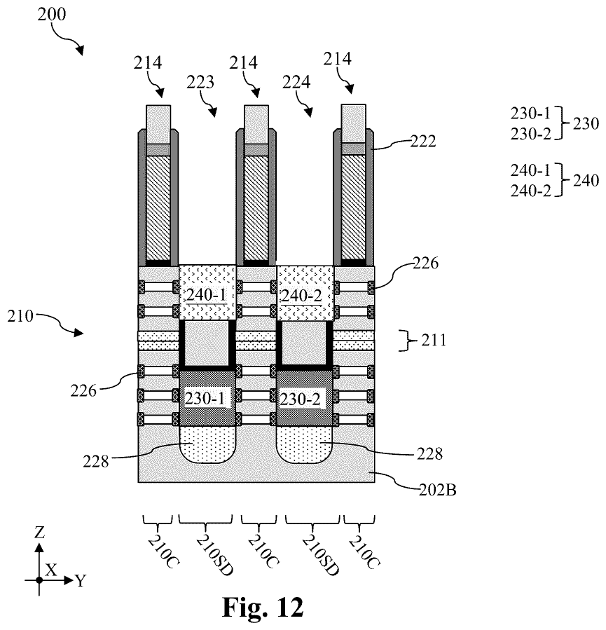

Referring to FIGS. 1 and 12, method 100 includes a block 122 where a first top source/drain feature 240-1 and a second top source/drain features 240-2 are formed. For case of reference, the first top source/drain feature 240-1 and the second top source/drain feature 240-2 may be collectively referred to as top source/drain features 240. The top source/drain features 240 may be formed using an epitaxial process, such as VPE, UHV-CVD, MBE, and/or other suitable processes. The epitaxial growth process may use gaseous and/or liquid precursors, which interact with composition of the channel layers 208 formed from the second stack structures 204T. The epitaxial growth of top source/drain features 240 may take place from the exposed sidewalls of the channel layers 208 formed from the second stack structures 204T. The deposited top source/drain features 240 are in physical contact with (or adjoining) the channel layers 208 formed from the second stack structures 204T. Depending on the design, the top source/drain features 240 may be n-type or p-type. In the depicted embodiments, the top source/drain features 240 are n-type source/drain features and may include silicon (Si) doped with an n-type dopant, such as phosphorus (P). In these depicted embodiments, the top source/drain features 240 may include phosphorus doped silicon (Si: P). In some alternative embodiments, the top source/drain features 240 are p-type source/drain features and may include boron-doped silicon germanium (SiGe: B).

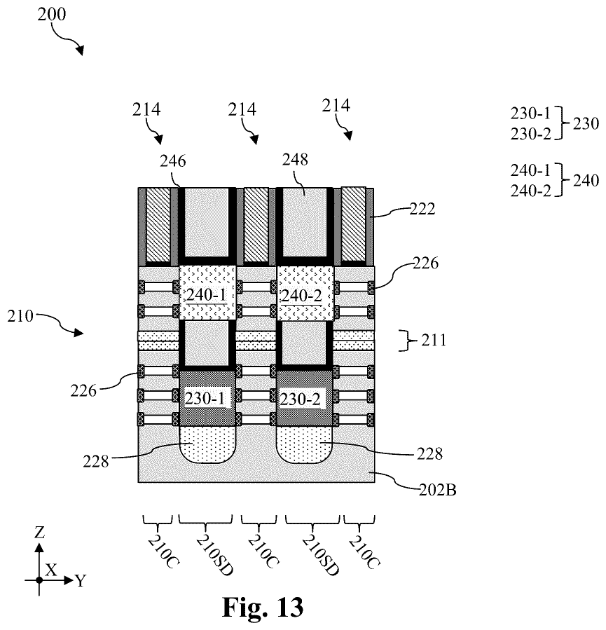

Referring to FIGS. 1 and 13, method 100 includes a block 124 where a top CESL 246 and a top ILD layer 248 are deposited over the first top source/drain feature 240-1 and second top source/drain features 240-2. The top CESL 246 may include silicon nitride, silicon oxynitride, and/or other materials known in the art and may be formed by CVD, ALD, plasma-enhanced chemical vapor deposition (PECVD) process and/or other suitable deposition or oxidation processes. In some embodiments, the top CESL 246 is first conformally deposited on the workpiece 200 and the ILD layer 248 is deposited over the top CESL 246 by spin-on coating, FCVD, CVD, or other suitable deposition technique. The top ILD layer 248 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the top ILD layer 248, the workpiece 200 may be annealed to improve integrity of the top ILD layer 248. To remove excess materials and to expose top surfaces of the dummy gate stacks 214, a planarization process, such a chemical mechanical polishing (CMP) process may be performed. The top CESL 246 is in direct contact with top surfaces of the top source/drain features 240 and sidewalls of the at least one gate spacer layer 222. The top ILD layer 248 is spaced apart from top surfaces of the top source/drain features 240 and sidewalls of the at least one gate spacer layer 222 by the top CESL 246.

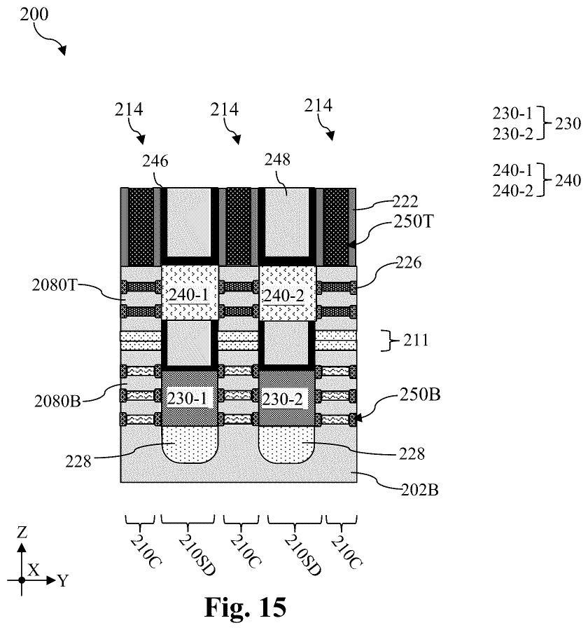

Referring to FIGS. 1, 14 and 15, method 100 includes a block 126 where the dummy gate stack 214 is replaced with a first gate structure 250B and a second gate structure 250T. Operations at block 126 may include removal of the dummy gate stacks 214, release of the channel layers 208 as bottom channel members 2080B and top channel members 2080T, and formation of a first gate structures 250B to wrap around each of the bottom channel members 2080B, and formation of a second gate structure 250T to wrap around each of the top channel members 2080T. The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. After the removal of the dummy gate stacks 214, sidewalls of the channel layers 208 and sacrificial layers 206 in the channel regions 210C are exposed. Thereafter, the sacrificial layers 206 in the channel regions 210C are selectively removed to release the channel layers 208 formed from the first stack structure 204B as the bottom channel members 2080B and channel layers 208 formed from the second stack structure 204T as the top channel members 2080T. As shown in FIG. 15, the bottom channel members 2080B are disposed below the bonding layers 211 and the top channel members 2080T are disposed over the bonding layer 211. Here, because the dimensions of the bottom channel members 2080B or top channel members 2080T are nanoscale, they may also be referred to as nanostructures. The selective removal of the sacrificial layers 206 may be implemented by selective dry etch, selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH.

With the bottom channel members 2080B and top channel members 2080T released, the first gate structure 250B is deposited to wrap around each of the bottom channel members 2080B, thereby forming a bottom multi-gate transistor. Similarly, the second gate structure 250T is deposited to wrap around each of the top channel members 2080T, thereby forming a top multi-gate transistor. In the depicted embodiments, both the bottom multi-gate transistor and the top multi-gate transistor are MBC transistors that includes vertically stacked channel members 2080. While not explicitly shown in the figures, each of the first gate structure 250B and the second gate structure 250T includes an interfacial layer to interface the channel members 2080, a gate dielectric layer over the interfacial layer, and a work function layer over the gate dielectric layer. In some embodiments, the interfacial layer includes silicon oxide and may be formed in a pre-clean process. An example pre-clean process may include use of RCA SC-1 (ammonia, hydrogen peroxide and water) and/or RCA SC-2 (hydrochloric acid, hydrogen peroxide and water). The gate dielectric layer is then deposited over the interfacial layer using ALD, CVD, and/or other suitable methods. The gate dielectric layer is formed of high-K dielectric materials. As used and described herein, high-k dielectric materials include dielectric materials having a high dielectric constant, for example, greater than that of thermal silicon oxide (˜3.9). The gate dielectric layer may include hafnium oxide. Alternatively, the gate dielectric layer may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material.

After the deposition of the gate dielectric layer, a p-type work function layer may be deposited to form the first gate structure 250B and an n-type work function layer may be deposited to form the second gate structure 250T. The p-type work function layer and the n-type work function layer may include a single layer or alternatively a multi-layer structure, such as various combinations of a metal layer with a selected work function to enhance the device performance (work function metal layer). By way of example, the p-type work function layer may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The n-type work function layer may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. Each of the first gate structure 250B and the second gate structure 250T may also include a metal fill to reduce contact resistance. In some instance, the metal fill includes tungsten (W). In the depicted embodiment, the bottom gate portion 250B includes a p-type work function layer and the top gate portion 250T includes a n-type work function layer.

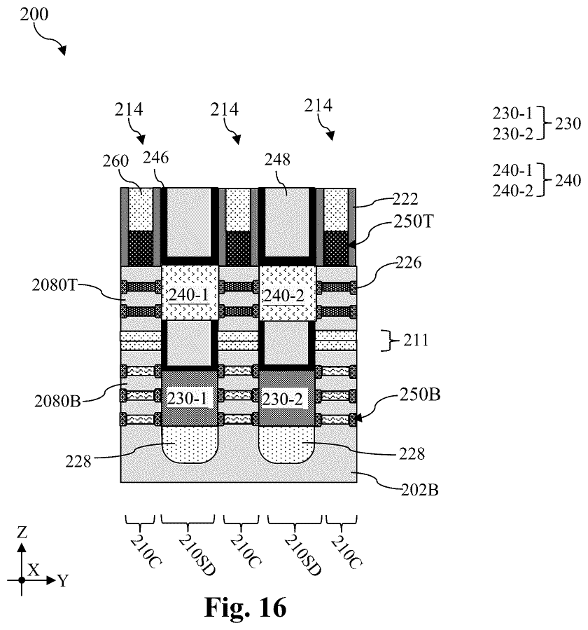

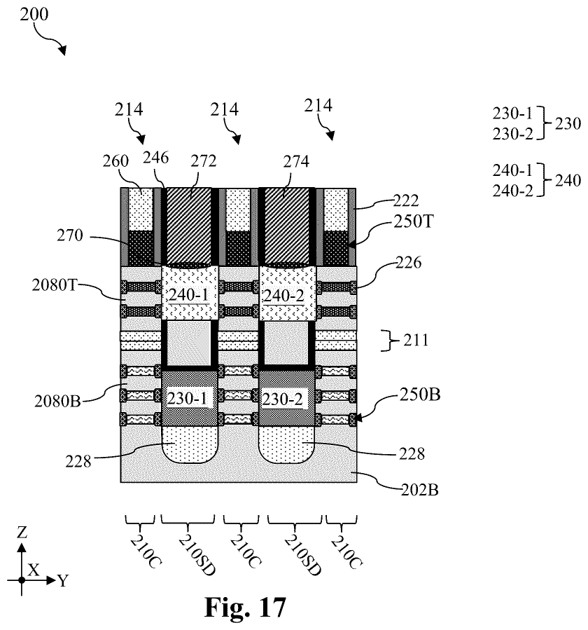

Referring to FIGS. 1, 16 and 17, method 100 includes a block 128 where further processes are performed. Such further processes may include formation of a self-aligned capping (SAC) layer 260 of the second gate structure 250T (shown in FIG. 16) and formation of a first source/drain contact 272 and a second source/drain contact 274 (shown in FIG. 17). Referring to FIG. 16, to make room for the SAC layer 260, the second gate structure 250T is selectively etched back while the at least one gate spacer layer 222 remains substantially unetched. A dielectric material for the SAC layer 260 is then deposited using ALD, CVD, or a suitable method. After excess material is removed by a planarization process, such as a CMP process, the SAC layer 260 is formed over the second gate structure 250T. The SAC layer 260 may include silicon nitride, silicon oxynitride, silicon oxycarbonitride, or a suitable material. Referring to FIG. 17, after the formation of the SAC layer 260, the top ILD layer 248 is selectively etched using a dry etch process, a wet etch process, or a combination thereof. After a bottom surface of the top CESL 246 is breached through using an anisotropic etch process, top surfaces of the top source/drain features 240 are exposed. A silicide feature 270 is then formed on the exposed surfaces of the top source/drain features 240. In an example process, a metal precursor (e.g., titanium (Ti), cobalt (Co), nickel (Ni), or tantalum (Ta)) is deposited over the workpiece 200. An anneal is then performed to bring about silicidation between the metal precursor and the exposed top source/drain features 240 to form the silicide features 270. Excess metal precursor that does not turn into the silicide features 270 may be optionally removed using a selective wet etch. In another example process, a metal halide precursor (e.g., titanium tetrachloride) and a silicon-containing precursor (e.g., SiH₄) are used in a CVD process to form the silicide features 270 on the top source/drain features 240. In some embodiments, the silicide features 270 may include titanium silicide, nickel silicide, cobalt silicide, or tantalum silicide. After the formation of the silicide features 270, a metal fill layer is deposited to form the first source/drain contact 272 and the second source/drain contact 274. In some instances, the metal fill layer may include cobalt (Co), nickel (Ni), tungsten (W), or copper (Cu).

In one exemplary aspect, the present disclosure is directed to a method. The method includes forming a first stack over a first substrate, the first stack including a first plurality of channel layers interleaved by a first plurality of sacrificial layers, forming a first bonding layer over the first stack, forming a second stack over a second substrate, the second stack including a second plurality of channel layers interleaved by a second plurality of sacrificial layers, forming a second bonding layer over the second stack, bonding the second bonding layer to the first bonding layer such that the second stack is disposed over the first stack to form a composite stack, after the bonding, removing the second substrate over the composite stack, patterning the composite stack to form a fin-shaped structure, form a dummy gate stack over a channel region of the fin-shaped structure, etching a source/drain region of the fin-shaped structure to form a source/drain trench, forming a bottom source/drain feature in the source/drain trench to contact sidewalls of the first plurality of channel layers, forming a top source/drain feature over the bottom source/drain feature to contact sidewalls of the second plurality of channel layers, selectively removing the first plurality of sacrificial layers and the second plurality of channel layers in the channel region of the fin-shaped structure to form bottom channel members and top channel members over the bottom channel members, forming a first gate structure to wrap around each of the bottom channel members, and forming a second gate structure to wrap around each of the top channel members.

In some embodiments, the first bonding layer and the second bonding layer include silicon oxide, silicon carbonitride, silicon nitride, silicon oxynitride, or silicon oxycarbonitride. In some embodiments, the bonding includes treating surfaces of the first bonding layer and the second bonding layer with a plasma of nitrogen (N2), oxygen (O2), or argon (Ar), bringing the first bonding layer and the second bonding layer in contact with one another, and after the bringing, performing an anneal to bond the first bonding layer and the second bonding layer. In some implementations, the bond further includes before the bringing, cleaning the surfaces of the first bonding layer and the second bonding layer with ammonia, hydrogen peroxide, hydrochloric acid, hydrogen peroxide, or water. In some embodiments, the forming of the first bonding layer includes depositing the first bonding layer using chemical vapor deposition (CVD) or atomic layer deposition (ALD). In some instances, the depositing includes a temperature below 600° C. In some embodiments, the forming of the first bonding layer includes depositing the first bonding layer using sputtering, and after the depositing, annealing the first bonding layer. In some embodiments, the first bonding layer and the second bonding layer include a thickness between about 1 nm and about 100 nm. In some embodiments, after the bonding, an observable interface exists between the first bonding layer and the second bonding layer.

In another exemplary aspect, the present disclosure is directed to a method. The method includes forming a first stack over a first substrate, the first stack including a first plurality of silicon layers interleaved by a first plurality of silicon germanium layers, forming a first bonding layer over the first stack, forming a second stack over a second substrate, the second stack including a second plurality of silicon layers interleaved by a second plurality of silicon germanium layers, forming a second bonding layer over the second stack, and bonding the second bonding layer to the first bonding layer such that the second stack is disposed over the first stack to form a composite stack, after the bonding, removing the second substrate, patterning the composite stack to form a fin-shaped structure, form a dummy gate stack over a channel region of the fin-shaped structure, forming a bottom source/drain feature over a source/drain region of the fin-shaped structure to contact sidewalls of the first plurality of silicon layers, forming a top source/drain feature over the bottom source/drain feature to contact sidewalls of the second plurality of silicon layers, releasing at least one of the first plurality of silicon layers as a bottom channel member, releasing at least one of the second plurality of silicon layers as a top channel member, forming a first gate structure to wrap around each of the bottom channel members, and forming a second gate structure to wrap around each of the top channel members. A germanium content in each of the first plurality of silicon germanium layer and each of the second plurality of silicon germanium layers is the same.

In some embodiments, the method further includes before the forming of the bottom source/drain feature, anisotropically etching the source/drain region of the fin-shaped structure to form expose sidewalls of the first plurality of silicon layers, the second plurality of silicon germanium layers, the first bonding layer, the second bonding layer, the second plurality of silicon layers, and the second plurality of silicon germanium layers. In some embodiments, the method further includes after the anisotropically etching, selectively recessing the sidewalls of the first plurality of silicon germanium layers and the sidewalls of the second plurality of silicon germanium layers to form inner spacer recesses, and forming inner spacer features in the inner spacer recesses to interleave the first plurality of silicon layers and the second plurality of silicon layers in the channel region. The selectively recessing does not substantially recess the sidewalls of the first bonding layer and the second bonding layer. In some embodiments, a composition of the inner spacer features is different from a composition of the first bonding layer and the second bonding layer. In some embodiments, the first bonding layer and the second bonding layer include silicon oxide, silicon carbonitride, silicon nitride, silicon oxynitride, or silicon oxycarbonitride. In some embodiments, the bonding includes treating surfaces of the first bonding layer and the second bonding layer with a plasma of nitrogen (N2), oxygen (O2), or argon (Ar), bringing the first bonding layer and the second bonding layer in contact with one another, and after the bringing, performing an anneal to bond the first bonding layer and the second bonding layer. In some instances, the bonding further includes before the bringing, cleaning the surfaces of the first bonding layer and the second bonding layer with ammonia, hydrogen peroxide, hydrochloric acid, hydrogen peroxide, or water.

In yet another exemplary aspect, the present disclosure is directed to a semiconductor structure. The semiconductor structure includes a first bottom source/drain feature and a second bottom source/drain feature disposed over a substrate, a plurality of bottom channel members extending between and in contact with the first bottom source/drain feature and the second bottom source/drain feature, a first bonding layer over the plurality of bottom channel members, a second bonding layer disposed directly on the first bonding layer, a first top source/drain feature disposed directly over the first bottom source/drain feature, a second top source/drain feature disposed directly over the second bottom source/drain feature, and a plurality of top channel members disposed over the second bonding layer and extending between and in contact with the first top source/drain feature and the second top source/drain feature.

In some embodiments, the semiconductor structure further includes a contact etch stop layer (CESL) disposed over the first bottom source/drain feature, and a dielectric layer disposed on the CESL. The CESL is in direct contact with a top surface of the first bottom source/drain feature, a sidewall of the first bonding layer, a sidewall of the second bonding layer, and a bottom surface of the first top source/drain feature. In some implementations, the dielectric layer is spaced apart from the top surface of the first bottom source/drain feature, the sidewall of the first bonding layer, and the sidewall of the second bonding layer by the CESL. In some instances, the semiconductor structure further includes a plurality of inner spacer features interleaving the plurality of bottom channel members. A composition of the plurality of inner spacer features is different from a composition of the first bonding layer and a second bonding layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a base fin extending from the substrate, the base fin comprising a channel region and a source/drain region adjacent the channel region;
an isolation feature over the substrate and interfacing sidewalls of the base fin;
a leakage blocking layer extending into the source/drain region of the base fin;
bottom channel layers disposed over the channel region of the base fin;
a bottom source/drain feature over the leakage blocking layer and interfacing end sidewalls of the bottom channel layers;
a first silicon layer over the bottom channel layers;
a first bonding layer over the first silicon layer;
a second bonding layer over the first bonding layer;
a second silicon layer over the second bonding layer;
top channel layers over the second silicon layer;
a top source/drain feature over the bottom source/drain feature and interfacing end sidewalls of the top channel layers;
a bottom gate structure wrapping around the bottom channel layers; and
a top gate structure wrapping around the top channel layers,
wherein the first bonding layer and the second bonding layer comprise silicon oxide, silicon carbonitride, silicon nitride, silicon oxynitride, or silicon oxycarbonitride,
wherein the first bonding layer is bonded to the second bonding layer.

2. The semiconductor structure of claim 1, further comprising:
a bottom contact etch stop layer (CESL) over the bottom source/drain feature; and
a bottom interlayer dielectric (ILD) layer over the bottom CESL.

3. The semiconductor structure of claim 2,
wherein the bottom CESL interfaces sidewalls of the first silicon layer, the first bonding layer, the second bonding layer, and the second silicon layer,
wherein the bottom ILD layer is spaced apart from the sidewalls of the first silicon layer, the first bonding layer, the second bonding layer, and the second silicon layer by the bottom CESL.

4. The semiconductor structure of claim 1, further comprising:
a pair of gate spacers disposed over a topmost one of the top channel layers,
wherein a top portion of the top gate structure is disposed between the pair of gate spacers.

5. The semiconductor structure of claim 4, further comprising:
a capping layer over the top gate structure,
wherein the capping layer is disposed between the pair of gate spacers.

6. The semiconductor structure of claim 5, wherein the capping layer comprises silicon nitride, silicon oxynitride, or silicon oxycarbonitride.

7. The semiconductor structure of claim 1, wherein the leakage blocking layer comprises an undoped semiconductor layer.

8. The semiconductor structure of claim 1,
wherein the bottom source/drain feature comprises silicon germanium and a p-type dopant,
wherein the top source/drain feature comprises silicon and an n-type dopant.

9. The semiconductor structure of claim 1,
wherein the bottom gate structure comprises a p-type work function layer, and
wherein the top gate structure comprises an n-type work function layer.

10. The semiconductor structure of claim 1, wherein the first bonding layer and the second bonding layer comprise a thickness between about 1 nm and about 100 nm.

11. A semiconductor structure, comprising:
a substrate;
a base fin extending from the substrate, the base fin comprising a channel region and a source/drain region adjacent the channel region;
an isolation feature over the substrate and interfacing sidewalls of the base fin;
a leakage blocking layer extending into the source/drain region of the base fin;
bottom channel layers disposed over the channel region of the base fin;
a bottom source/drain feature over the leakage blocking layer and interfacing end sidewalls of the bottom channel layers;
a bottom contact etch stop layer (CESL) over the bottom source/drain feature;
a bottom interlayer dielectric (ILD) layer over the bottom CESL;
a first silicon layer over the bottom channel layers;
a first bonding layer over the first silicon layer;
a second bonding layer over the first bonding layer;
a second silicon layer over the second bonding layer;
top channel layers over the second silicon layer;
a top source/drain feature over the bottom source/drain feature and interfacing end sidewalls of the top channel layers, the top source/drain feature being disposed over the bottom CESL and the bottom ILD layer;
a bottom gate structure wrapping around the bottom channel layers; and
a top gate structure wrapping around the top channel layers,
wherein the first bonding layer and the second bonding layer comprise silicon oxide, silicon carbonitride, silicon nitride, silicon oxynitride, or silicon oxycarbonitride,
wherein the first bonding layer is bonded to the second bonding layer.

12. The semiconductor structure of claim 11,
wherein the bottom CESL interfaces sidewalls of the first silicon layer, the first bonding layer, the second bonding layer, and the second silicon layer,
wherein the bottom ILD layer is spaced apart from the sidewalls of the first silicon layer, the first bonding layer, the second bonding layer, and the second silicon layer by the bottom CESL.

13. The semiconductor structure of claim 11, further comprising:
a pair of gate spacers disposed over a topmost one of the top channel layers,
wherein a top portion of the top gate structure is disposed between the pair of gate spacers.

14. The semiconductor structure of claim 13, further comprising:
a capping layer over the top gate structure,
wherein the capping layer is disposed between the pair of gate spacers.

15. The semiconductor structure of claim 14, wherein the capping layer comprises silicon nitride, silicon oxynitride, or silicon oxycarbonitride.

16. The semiconductor structure of claim 11,
wherein the bottom gate structure comprises a p-type work function layer, and
wherein the top gate structure comprises an n-type work function layer.

17. A semiconductor structure, comprising:
a base fin comprising a first source/drain region, a second source/drain region, and a channel region between the first source/drain region and the second source/drain region;
a first leakage blocking layer over the first source/drain region;
a second leakage blocking layer over the second source/drain region;
a first bottom source/drain feature over the first leakage blocking layer;
a second bottom source/drain feature over the second leakage blocking layer;
bottom nanostructures extending between and in contact with the first bottom source/drain feature and the second bottom source/drain feature;
a bottom gate structure wrapping around the bottom nanostructures;
a first bonding layer over bottom nanostructures;
a second bonding layer over and bonded to the first bonding layer;
a first top source/drain feature disposed directly over the first bottom source/drain feature;
a second top source/drain feature disposed directly over the second bottom source/drain feature;
top nanostructures disposed over the second bonding layer and extending between and in contact with the first top source/drain feature and the second top source/drain feature; and
a top gate structure wrapping around the top nanostructures.

18. The semiconductor structure of claim 17, further comprising:
a bottom contact etch stop layer (CESL) disposed over the first bottom source/drain feature; and
a dielectric layer disposed on the bottom CESL,
wherein the bottom CESL is in direct contact with a top surface of the first bottom source/drain feature, a sidewall of the first bonding layer, a sidewall of the second bonding layer, and a bottom surface of the first top source/drain feature,
wherein the dielectric layer is spaced apart from a top surface of the first bottom source/drain feature, a sidewall of the first bonding layer, a sidewall of the second bonding layer by the bottom CESL.

19. The semiconductor structure of claim 17, further comprising:
a plurality of inner spacer features interleaving the bottom nanostructures,
wherein a composition of the plurality of inner spacer features is different from a composition of the first bonding layer and the second bonding layer.

20. The semiconductor structure of claim 17,
wherein the bottom gate structure comprises a p-type work function layer, and
wherein the top gate structure comprises an n-type work function layer.
